(19) United States
(12) Patent Application Publication
(10) Pub. No.: US 2024/0273256 A1
(43) Pub. Date: Aug. 15, 2024

(54) DIGITAL TWIN SYSTEM FOR OPTIMIZED DESIGN AND VERIFICATION OF PEROVSKITE SOLAR CELL

(71) Applicant: Korea Electronics Technology Institute, Seongnam-si (KR)

(72) Inventors: Jaekyu Lee, Yongin-si (KR); Sang Yub Lee, Yongin-si (KR); Inpyo Cho, Yongin-si (KR)

(21) Appl. No.: 18/440,137

(22) Filed: Feb. 13, 2024

(30) Foreign Application Priority Data
Feb. 14, 2023 (KR) 10-2023-0019670
Feb. 7, 2024 (KR) 10-2024-0018707

(51) Int. Cl. G06F 30/20; G06N 5/04

(52) U.S. Cl. CPC G06F 30/20; G06N 5/04

(57) ABSTRACT

Proposed is a digital twin system for digitizing technologies related to development of perovskite solar cells, performing design, test, simulation, and verification on materials, physical/chemical properties, and structures in a virtual environment, and designing and manufacturing an optimal perovskite solar cell. The digital twin system may provide a digital twin system for, when developing perovskite solar cells, identifying the efficiency of solar cells without directly conducting experiments, and through simulation of various environments using various learning/inference models, optimally designing perovskite-based solar cells. Also proposed is a digital twin system that is designed with a machine learning operations (MLOps) structure to have a configuration in which initially designed learning/inference models are updated to resemble the real environment as the learning/inference models undergo experiments, enabling testing in a more realistic virtual environment.

### CROSS-REFERENCE TO RELATED APPLICATION

This application claims priority to and the benefit of Korean Patent Applications No. 2023-0019670 filed on Feb. 14, 2023, and 2024-0018707 filed on Feb. 7, 2024, the disclosures of which are incorporated herein by reference in their entireties.

### BACKGROUND

### Technical Field

The present disclosure relates to a digital twin service, and specifically, to a digital twin system for optimized design and verification of perovskite solar cells.

### Description of Related Technology

“Perovskite” is a word referring to a crystal structure of a material, named after a mineral called calcium titanium oxide (CaTiO₃), referring to a next-generation solar cell material that may replace poly-silicon (polycrystalline silicon). Since perovskite has ⅓ to 1/10 of the production cost of poly-silicon and allows for manufacturing of semi-transparent device, it can be applied to buildings, vehicles, solar panels, etc., and has high scalability.

### SUMMARY

One aspect is a digital twin system for optimized design and verification of perovskite solar cells that is capable of digitizing technologies related to development of perovskite solar cells, by performing design, test, simulation, and verification on materials, physical and chemical properties, and structures in a virtual environment, and by designing and manufacturing an optimal perovskite solar cell.

Another aspect is a digital twin system for, when developing perovskite solar cells, identifying the efficiency of solar cells without directly conducting experiments, and through simulation of various environments by using various learning and inference models, thereby optimally designing and verifying perovskite-based solar cells.

In addition, the present disclosure provides a digital twin system that is designed with a machine learning operations (MLOps) structure such that initially established learning/inference models are updated to resemble the real environment as the learning/inference models undergo experiments, enabling testing in a more realistic virtual environment.

Another aspect is a digital twin system, including: an integrated database in which accumulated data on perovskite materials and design technology is collected and stored; a learning and inference model configured to learn and infer physical and chemical structures of perovskite to identify and predict electrical properties according to a perovskite cell structure; a design module configured to design a perovskite solar cell in a virtual environment using the learning and inference model; a simulation module configured to simulate properties and structures of molecules of a material of the designed perovskite solar cell and a bond between the molecules; and a verification module configured to verify the designed perovskite solar cell.

The digital twin system may further include an Open application programming interface (OpenAPI) for operation of the learning and inference model, sharing of the collected data, design, simulation, joint development, and securing interoperability.

The learning and inference model may include a physical model configured to predict, based on physical laws, physical properties of the perovskite solar cell and an atomic or molecular structure of materials of the perovskite solar cell. Further, the learning and inference model may include a data model configured to predict an atomic or molecular structure of materials of the perovskite solar cell based on data. Still further, the learning and inference model may include a hybrid model configured to predict physical properties of the perovskite solar cell and an atomic or molecular structure of materials of the perovskite solar cell based on physical laws and data.

The design model may include: a front side design portion configured to design materials that form a front side of the perovskite solar cell based on a light absorption rate; a middle layer design portion configured to design materials that form a middle layer of the perovskite solar cell based on a charge loss and a charge transfer; a rear side design portion configured to design materials forming a rear side of the perovskite solar cell based on an absorption of spectrum of light remaining after passing through the middle layer; and a protective layer design portion configured to design materials that form a protective layer of the perovskite solar cell based on an influence of an external environment and safety of a solar cell. Further, the design module may include an optimized design portion configured to optimize a thickness of each layer and interaction between cells of the perovskite solar cell.

The verification module may be further configured to perform synthesis on a material derived from the virtual environment in a real environment to identify synthetic characteristics of the material.

The digital twin system of the present disclosure may further include a visualization module configured to visualize atomic and molecular structures derived for design of the perovskite solar cell.

The configuration of the present disclosure introduced above will become apparent through embodiments described below in conjunction with the accompanying drawings.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings.

FIG. 1 is a conceptual diagram illustrating a digital twin system for optimized design and verification of perovskite solar cells according to the present disclosure.

FIG. 2 is a block diagram illustrating a digital twin system according to an embodiment of the present disclosure.

FIG. 3 is a configuration diagram illustrating a design module shown in FIG. 2.

FIG. 4 is an example of an intermolecular bonding structure that may be simulated by a simulation module.

FIG. 5 is a diagram for describing actual environment verification of a verification module.

FIG. 6 is a block diagram illustrating a computer system that is the basis of the digital twin system according to the present disclosure.

### DETAILED DESCRIPTION

A “tandem cell,” which is one type of perovskite solar cell, has a structure in which upper cells are formed of perovskite, which absorbs light of short wavelengths, and lower cells are formed of silicon cells, which mainly absorb light of long wavelengths. The upper cells and the lower cells are bonded to each other. With the two cells being bonded, the perovskite solar cell has an inter-complementary light absorption effect. Currently, in the development of perovskite solar cells, the designing and testing of the structure are mostly performed in heuristic ways and so there is a significant difference in performance even under the same environment and conditions. In addition, since the test environment and know-how are not disclosed in papers or patents, it is very difficult to reproduce the experiments.

Meanwhile, “digital twin” is a technology of analyzing various types of data collected from the real world in a virtual world that is a replication of the real world (objects, spaces, processes, etc.), deriving optimization plans, and optimizing the real world based on the derived optimization plans to support testing, control (monitoring, regulation, etc.), simulation, and various decision-making. Recently, as element technologies such as big data analysis, modeling and simulation, networks and the like have developed, digital twins have been attracting attention as a technology that resolves various industrial and social issues beyond a manufacturing field that first adopted the digital twin technology.

Most of the conventional art related to perovskite solar cells focuses on materials and manufacturing methods, and there is no conventional art regarding digital twins or learning/inference models, for experiments or simulations.

The advantages and features of the present disclosure and ways of achieving them will become readily apparent with reference to the following embodiments described in detail in conjunction with the accompanying drawings. However, the present disclosure is not limited to such embodiments and may be embodied in various forms. The embodiments to be described below are provided only to make the disclosure of the present disclosure complete and assist those of ordinary skill in the art in fully understanding the scope of the present disclosure, and the scope of the present disclosure is defined only by the appended claims. Terms used herein are used for describing the embodiments and are not intended to limit the scope and spirit of the present disclosure. It should be understood that the singular forms “a” and “an” also include the plural forms unless the context clearly dictates otherwise. The terms “comprises,” “comprising,” “includes,” and/or “including” used herein specify the presence of stated features, integers, steps, operations, elements, components and/or groups thereof and do not preclude the presence or addition of one or more other features, integers, steps, operations, elements, components, and/or groups thereof.

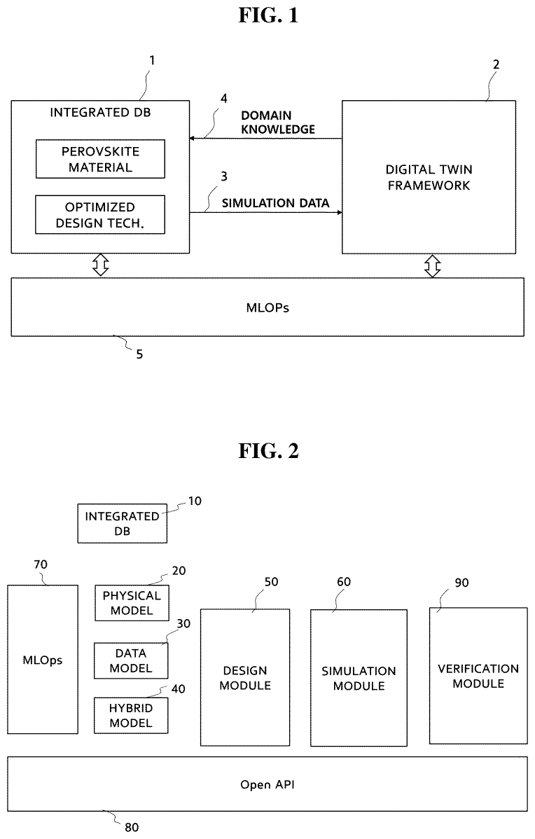

FIG. 1 is a conceptual diagram of a digital twin system for optimized design and verification of perovskite solar cells or tandem cells according to the present disclosure.

The digital twin system includes an integrated DB 1 built with data accumulated in technology related to perovskite materials and optimized design technology, and a digital twin framework 2 that performs optimized design and verification on perovskite solar cells in a virtual environment using various learning and inference models (hereinafter abbreviated as “models”). Additionally, the digital twin framework 2 may perform simulation with simulation data 3 built in the integrated DB 1 and transfer domain knowledge 4 thus generated to the integrated DB 1 to update the integrated DB 1. The digital twin system according to the present disclosure may be operated based on a machine learning operations (MLOps) environment 5. MLOps is a methodology for increasing the productivity of machine learning models and optimizing operational stability. The MLOps may include the entire process (referred to as an artificial intelligence (AI) lifecycle as a technical term) from an operation of collecting and analyzing data to an operation of training machine learning models and deploying the trained machine learning models.

FIG. 2 is a configuration diagram of an embodiment of the digital twin system of the above concept. The digital twin system according to the embodiment may include an integrated DB 10 in which data accumulated on technology related to perovskite materials and optimized design technology is collected and stored; software models for simulating physical and chemical structures of perovskite to identify and predict the electrical properties according to the perovskite cell structure, the software models including a physical model (e.g., a library related to physical properties) 20, a data model 30, and a hybrid model 40; a design module (or a design processor) 50 for designing a perovskite solar cell in a virtual environment using one or more of the physical model 20, the data model 30, and the hybrid model 40 (e.g., using the physical model 20); a simulation module (or a simulation processor)) 60 for performing simulation (test) on the designed perovskite solar cell using one or more of the physical model 20, the data model 30, and the hybrid model 40 (e.g., using the hybrid model 40) to derive the optimum structure, an MLOps environment 70 for optimization of the physical model 20, the data model 30, and the hybrid model 40; an Open application programming interface (OpenAPI) 80 for operation of the models, sharing of collected data, optimized design, simulation, joint development, and securing interoperability; and a verification module (or a verification processor) 90 for verification of the perovskite solar cell.

The integrated DB 10 is built to store simulation data and optimized design data such that data related to perovskite material technology and perovskite solar cell design is accumulated therein to be used for optimized design and verification of perovskite solar cells. In the integrated DB 10, data on the structures of atoms/molecules that may be used as materials for perovskite solar cells, and density functional theory (DFT)-related data (a molecular structure, an electronic structure, a band structure, a thermodynamic value, a dielectric constant, formation energy, etc.) of various molecules are collected. These data may be collected through a digital twin-based hybrid model 40. In addition, since a large amount of data is generated in the hybrid model 40, it is preferable that the integrated DB 10 is composed of a database with a high availability big data structure, for efficient data collection. The high-availability database may be designed based on Docker containers and implemented using Galea Cluster based on MariaDB MaxScale.

The physical model 20 may be a model that predicts the molecular structure of a tandem cell. This model may predict atomic or molecular structure through simulation of physical properties and devices based on physical laws. For such a simulation, a model such as physics-informed neural networks (PINN) may be included in the physical model 20.

The data model 30 may be a model that predicts the structure of atoms usable as a perovskite material and predicts physical properties, such as a graph neural network (GNN).

The hybrid model 40 may be a model in which the physical model 20 and the data model 30 are combined, and the data-based model (i.e., the data model 30) and the simulation-based physical model 20 are combined. The data model 30 obtains high accuracy by collecting data in an actual experimental environment, but it may be difficult to collect real data needed to train the model. On the other hand, the physical model 20 operating based on simulation may generate data without actual data. However, simulation-based models require many computing resources and have slow calculation speeds. A model that complements the shortcomings and utilizes the strengths of the data-based model and the simulation-based model is the hybrid model 40. The hybrid model 40 may complement the data model 30 and the physical model 20 and more accurately predict the structure of the atoms or molecules that may be used in perovskite solar cells.

The physical model 20, the data model 30, and the hybrid model 40 may be implemented as an integrated configuration that includes data and learning/inference models required for optimized design and molecular structure prediction of perovskite tandem cells.

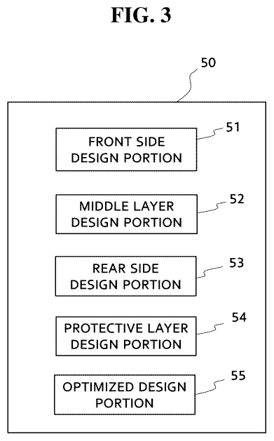

The design module 50 for optimized design of perovskite solar cells designs perovskite solar cells with optimal materials suitable for the characteristics of the structure of a perovskite solar cell. Since the structure of a perovskite solar cell (or tandem cell) may be largely composed of a front side, a middle layer, a rear side, and a protective layer, the design module 50 may be configured to design the optimal material for each part. For example, the design module 50 may include a front side design portion 51, a middle layer design portion 52, a rear side design portion 53, and a protective layer design portion 54 (see FIG. 3).

First, the front side of the perovskite solar cell needs to efficiently absorb light. Therefore, the front side design portion 51 may design the materials that form the front side of the perovskite solar cell as materials having a high light absorption rate. Since the middle layer is a layer in which effective charge transfer is important, the middle layer design portion 52 may design the middle layer based on materials minimizing charge loss and supporting stable charge transfer. Additionally, the rear side design portion 53 may design the rear side with a material that may effectively absorb a spectrum of light remaining after passing through the middle layer. The protective layer design portion 54 may derive materials that minimize the impact of the external environment and maintain the safety of perovskite solar cells, and may design the protective layer.

Additionally, the design module 50 may include an optimized design portion 55 for optimizing the thickness of each layer and the interaction between unit cells of the perovskite solar cell.

The simulation module 60 for simulating the designed perovskite solar cell may simulate the properties and structures of molecules predicted using one or more of the physical model 20, the data model 30, and the hybrid model 40, and the bond between each molecule. In other words, the simulation module 60 is not provided to combine or experiment on molecules in a real environment, but to predict the molecular structure and perform experimentation and synthesis in a virtual environment and derive the optimal material for developing perovskite solar cells.

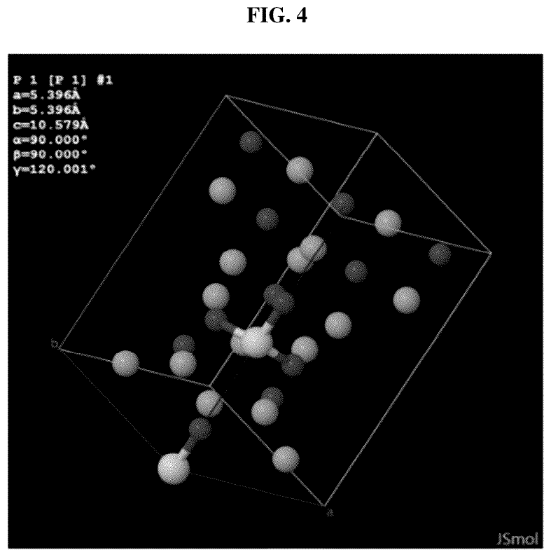

The molecular bonding structure that may be simulated by the simulation module 60 is illustrated in FIG. 4.

The MLOps environment 70 for optimizing the physical model 20, the data model 30, and the hybrid model 40 may include all structures required for the operation of MLOps technology for machine learning and optimization of the physical model 20, the data model 30, and the hybrid model 40.

The verification module 90 performs verification on materials predicted and generated from the learning and prediction (inference) models, that is, the physical model 20, the data model 30, and the hybrid model 40. Based on the known chemical knowledge, or based on an accumulated database, the verification module 90 may simulate synthesis of material to see whether actual materials may be synthesized, and verify the properties of the synthesized materials. The scope of verification does not only include the virtual environment, but may also include a process of performing the synthesis of a material, which is derived through the virtual environment, in the real environment and identifying the synthetic characteristics of the material.

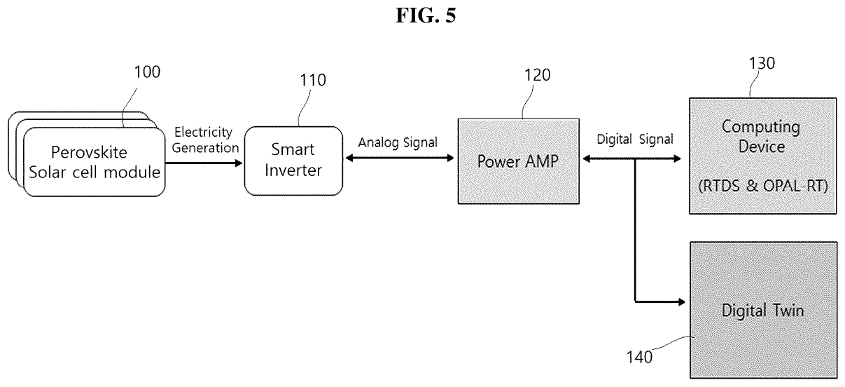

For example, as shown in FIG. 5, the verification module 90 may simulate a perovskite solar module 100, which is developed based on a designed new material or molecular structure, in a digital twin environment 140 to simulate how efficient the perovskite solar module 100 is when compared to the existing solar modules and how much power the perovskite solar module 100 generates. In addition, the verification module 90 may simulate the perovskite solar module 100 as in a real situation using a smart inverter 110 and a power amplifier 120, and may analyze the impact on a power system through a real-time digital simulator (RTDS)/OPAL-RT tool 130 for simulating and analyzing a power system and a control system.

Data verified in the real environment is transferred back to the digital twin or virtual environment, allowing the verification module 90 to have a complementary structure in which virtual environment data is supplemented based on real environment experiments. This provides an effect of supplementing models and data as in the MLOps structure.

The verification module 90 may also simulate the characteristics and performance of the developed perovskite solar module 100 through a mixed simulation with the existing renewable energy generators (solar energy, wind power, etc.) based on the digital twin.

The digital twin system according to the present disclosure may further include a visualization module (or a visualization processor) (not shown) in addition to the components shown in FIG. 2.

The visualization module may visualize the atomic and molecular structures derived for optimized design of perovskite solar cells, and may output the bonding structure and state of material molecules verified through the verification module 90. The visualization module may include reduced order modeling to reduce the computational load required for two-dimensional (2D) or three-dimensional (3D) visualization.

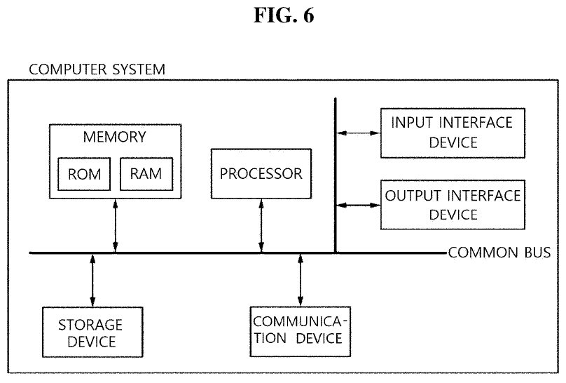

The digital twin system according to the present disclosure described above may be implemented as hardware and/or software programs (or applications) based on a computer system illustrated in FIG. 6.

Referring to FIG. 6, the computer system may include at least one of a processor, a memory, an input interface device, an output interface device, and a storage device that is communicated through a common bus. The computer system may also include a communication device coupled to a network. The processor may be a central processing unit (CPU) or a semiconductor device for executing instructions stored in the memory and/or storage device. The communication device may transmit or receive a wired signal or wireless signal. The memory and the storage device may include various forms of volatile or nonvolatile media. The memory may include a read only memory (ROM) or a random access memory (RAM). The memory may be located inside or outside the processor and may be connected to the processor through various known means.

The software program may include codes encoded in a computer language such as C, C++, Java, a machine language, etc., that can be read by the computer through a device interface of the computer in order to operate or control a digital twin system for optimized design and verification of perovskite solar cells according to the present disclosure. The code may include functional code that is related to a function that defines functions needed to execute the methods and may include execution procedure-related control code needed to cause the processor of the computer to execute the functions according to a predetermined procedure. In addition, the code may further include memory reference-related code as to whether additional information or media needed to cause the processor of the computer to execute the functions should be referenced at a location (an address) of an internal or external memory of the computer. In addition, when the processor of the computer needs to communicate with any other computers or servers, etc. at a remote site, to perform the above-described functions, the code may further include communication-related code such as how to communicate with any other computers or servers at a remote site and what information or media should be transmitted or received during communication.

Meanwhile, the software program may be implemented in the form of program instructions executable by various computer devices and may be recorded in computer readable media. The computer-readable media are media that semi-permanently store data and may be readable by a device, rather than media that store images for a short period of time, such as registers, caches, and memories. The computer readable media may include program instructions, data files, data structures, and the like alone or in combination. The program instructions stored in the computer readable media may be specially designed and constructed for the purposes of the embodiments of the present disclosure or may be well known and available to those having skill in the art of computer software. The computer readable storage media include hardware devices configured to store and execute program instructions. The program instructions include not only machine language code made by a compiler but also high level code that can be used by an interpreter etc., which is executed by a computer. For example, the computer readable storage media include magnetic media such as hard disks, floppy disks, and magnetic tape, optical media such as CD-ROMs and DVDs, magneto-optical media such as floptical disks, ROMs, RAMs, flash memories, etc.

As is apparent from the above, the present disclosure provides the first digital twin system for design and verification including learning/inference models related to perovskite solar cells that can, in development of perovskite solar cells, provide optimized design, simulation and verification technologies, by using virtual screening of materials with a knowledge base. The digital twin system according to the present disclosure is expected to serve as an essential platform for developing next-generation solar cells and establish technology diffusion through OpenAPI.

While embodiments of the present disclosure have been described in detail, it should be understood that the technical scope of the present disclosure is not limited to the embodiments and drawings described above, and is determined by a rational interpretation of the scope of the claims.

What is claimed is:

1. A digital twin system comprising:
an integrated database configured to collect and store accumulated data on perovskite materials and design technology;
a learning and inference model configured to learn and infer physical and chemical structures of perovskite to identify and predict electrical properties according to a perovskite cell structure;
a design processor configured to design a perovskite solar cell in a virtual environment using the learning and inference model;
a simulation processor configured to simulate properties and structures of molecules of a material of the designed perovskite solar cell and a bond between the molecules; and
a verification processor configured to verify the designed perovskite solar cell.

2. The digital twin system of claim 1, further comprising an open application programming interface (OpenAPI) configured to operate the learning and inference model, and share the collected data, design, simulation, joint development, and securing interoperability.

3. The digital twin system of claim 1, wherein the learning and inference model includes a physical model configured to predict physical properties of the perovskite solar cell and an atomic or molecular structure of materials of the perovskite solar cell based on physical laws.

4. The digital twin system of claim 1, wherein the learning and inference model includes a data model configured to predict an atomic or molecular structure of materials of the perovskite solar cell based on data.

5. The digital twin system of claim 1, wherein the learning and inference model includes a hybrid model configured to predict physical properties of the perovskite solar cell and an atomic or molecular structure of materials of the perovskite solar cell based on physical laws and data.

6. The digital twin system of claim 1, wherein the design processor includes:
a front side design processor configured to design materials that form a front side of the perovskite solar cell based on a light absorption rate;
a middle layer design processor configured to design materials that form a middle layer of the perovskite solar cell based on a charge loss and a charge transfer;
a rear side design processor configured to design materials forming a rear side of the perovskite solar cell based on an absorption of spectrum of light remaining after passing through the middle layer; and
a protective layer design processor configured to design materials that form a protective layer of the perovskite solar cell based on an influence of an external environment and safety of a solar cell.

7. The digital twin system of claim 6, wherein the design processor further includes an optimized design processor configured to optimize a thickness of each layer and interaction between cells of the perovskite solar cell.

8. The digital twin system of claim 1, wherein the verification processor is further configured to perform synthesis on a material derived from the virtual environment in a real environment to identify synthetic characteristics of the material.

9. The digital twin system of claim 1, further comprising a visualization processor configured to visualize atomic and molecular structures derived for design of the perovskite solar cell.
